(19) United States
(12) Patent Application Publication
(10) Pub. No.: US 2012/0262220 A1
(43) Pub. Date: Oct. 18, 2012

(54) CASCODE SWITCHES INCLUDING NORMALLY-OFF AND NORMALLY-ON DEVICES AND CIRCUITS COMPRISING THE SWITCHES

(75) Inventor: Nigel SPRINGETT, Emmendingen (DE)

(73) Assignee: SEMISOUTH LABORATORIES, INC., Starkville, MS (US)

(21) Appl. No.: 13/085,648

(22) Filed: Apr. 13, 2011

(51) Int. Cl. H03K 17/687

(52) U.S. Cl. 327/430; 327/427; 327/434

(57) ABSTRACT

Switches comprising a normally-off semiconductor device and a normally-on semiconductor device in cascode arrangement are described. The switches include a capacitor connected between the gate of the normally-on device and the source of the normally-off device. The switches may also include a zener diode connected in parallel with the capacitor between the gate of the normally-on device and the source of the normally-off device. The switches may also include a pair of zener diodes in series opposing arrangement between the gate and source of the normally-off device. Switches comprising multiple normally-on and/or multiple normally-off devices are also described. The normally-on device can be a JFET such as a SiC JFET. The normally-off device can be a MOSFET such as a Si MOSFET. The normally-on device can be a high voltage device and the normally-off device can be a low voltage device. Circuits comprising the switches are also described.

### BACKGROUND

1. Field

This application relates generally to semiconductor devices and, in particular, to switches comprising a normally-off device and a normally-on high voltage device in cascode arrangement and circuits comprising the switches.

2. Background of the Technology

A source-switched circuit, which is often referred to as “cascode,” is a composite circuit including a normally-off gating device with a normally-on high-voltage device so that the combination operates as a normally-off high power semiconductor device. The device has three external terminals, the source, gate, and drain. The gating device can be a low-voltage power semiconductor device which can switch rapidly with small drive signals. This gating device can be a low-voltage field effect transistor which has its drain terminal connected to the source terminal of the high-voltage, normally-on device. The addition of protection devices on the gate of the control device can be used to simplify layout and enhance device reliability. The composite circuit is suitable for packaging as a three-terminal device for use as a transistor replacement.

Cascode circuits are disclosed in U.S. Pat. No. 4,663,547, U.S. Pat. No. 7,719,055, U.S. Pat. No. 6,822,842 B2, U.S. Pat. No. 6,55,050 B2 and U.S. Pat. No. 6,633,195 B2.

There still exists a need, however, for cascode switching devices having low switching losses and improved control over switching speed.

### SUMMARY

A switch is provided which comprises:

a first normally-on semiconductor device comprising a gate, a source and a drain;

a first normally-off semiconductor device comprising a gate, a source and a drain;

wherein the source of the first normally-on semiconductor device is connected to the drain of the first normally-off semiconductor device; and

wherein the gate of the first normally on semiconductor device is connected to the source of the first normally-off semiconductor device via a first capacitor.

A circuit comprising a switch as set forth above is also provided.

These and other features of the present teachings are set forth herein.

### BRIEF DESCRIPTION OF THE DRAWINGS

The skilled artisan will understand that the drawings, described below, are for illustration purposes only. The drawings are not intended to limit the scope of the present teachings in any way.

FIG. 1A is a schematic of a switch comprising a normally-off device Q4 and a normally-on device Q1 in cascode arrangement wherein a capacitor C6 and a zener diode D3 are connected in parallel with one another between the source of the normally-off device and the gate of the normally-on device and a pair of zener diodes D5 and D6 are connected in series opposing arrangement between the gate and the source of the normally-off device

FIG. 1B is a schematic of a switch as set forth in FIG. 1A which also comprises a pair of diodes D1 connected in parallel with one another between the source of the normally-off device Q4 and the drain of the normally-on device Q1 wherein the cathodes of the diodes D1 are connected to the drain of the normally-on device.

FIG. 1C is a schematic of a switch as set forth in FIG. 1A which also comprises a capacitor C7 and a zener diode D7 across the normally-off device Q4.

FIG. 2A is a switch as set forth in FIG. 1A which also comprises a diode D2 and a resistor R1 connected in series between the gate of the normally-off device Q4 and the electrical connection between the capacitor C6 and the gate of the normally-on device Q1.

FIG. 2B is a switch as set forth in FIG. 1A which also comprises a DC power supply connected to the electrical connection between the capacitor C6 and the gate of the normally-on device Q1 via a diode D2 and a resistor R1 in series.

FIG. 3 is a schematic of a switch comprising a normally-off device Q4 and a normally-on device Q1 connected in cascode arrangement wherein a capacitor C6 and a zener diode D3 are shown connected in parallel with one another between the source of the normally-off device Q4 and the gate of the normally-on device Q1 and wherein a resistor R100 and a diode D100 are also shown connected in parallel with one another and in series with the capacitor C6 and the zener diode D3 between the capacitor C6 and a zener diode D3 and the gate of the normally-on device Q1 and wherein the cathodes of the zener diode D3 and the diode D100 are both connected to the gate of the normally-on device.

FIG. 4 is a schematic of a switch comprising a normally-off device Q4 and a normally-on device Q1 connected in cascode arrangement wherein a capacitor C6 and a zener diode D3 are shown connected in parallel with one another between the source of the normally-off device Q4 and the gate of the normally-on device Q1 and wherein a resistor R100 and a diode D101 are also shown connected in parallel with one another and in series with the capacitor C6 and a zener diode D3 between the capacitor C6 and a zener diode D3 and the gate of the normally-on device and wherein the cathode of the zener diode D3 and the anode of the diode D101 are connected to the gate of the normally-on device Q1.

FIG. 5 is a schematic of a switch as set forth in FIG. 1A which also comprises a resistor 8200 and a capacitor C200 connected in series between the gate of the normally-off device Q4 and the drain of the normally-on device Q1.

FIG. 6 is a schematic of a switch comprising a single normally-off device Q4 having a gate, a source and a drain and a plurality of normally-on devices Q1₁-Q1ₙ each having a gate, a source and a drain wherein a single capacitor C6 and a single zener diode D3 are shown connected in parallel with one another between the source of the normally-off device Q4 and the common gate of the normally-on devices Q1₁-Q1ₙ.

FIG. 7 is a schematic of a switch comprising a single normally-off device Q4 having a gate, a source and a drain and a plurality of normally-on devices Q1₁-Q1ₙ each having a gate, a source and a drain wherein a separate capacitor C6₁-C6ₙ and zener diode D3₁-D3ₙ are connected in parallel with one another between the source of the normally-off device Q4 and the gates of each of the normally-on devices Q1₁-Q1ₙ.

FIG. 8 is a schematic of a switch comprising a plurality of normally-off devices Q4ₙ each having a gate, a source and a drain and a plurality of normally-on devices Q1ₙ each having a gate, a source and a drain wherein a single capacitor C6 and a single zener diode D3 are shown connected in parallel with one another between the common sources of the normally-off devices and the common gates of the normally-on devices.

FIG. 9 is a schematic of a switch comprising a single normally-off device Q4 having a gate, a source and a drain and a plurality of normally-on devices divided into a first group Q1₁-Q1ₙ (Q1₁ and Q1₂ shown) and a second group Q2₁-Q2ₙ. (Q2₁ and Q2₂ shown) each having a gate, a source and a drain wherein a first capacitor C6₁ and a first zener diode D3₁ are shown connected in parallel with one another between the source of the normally-off device and the common gate of the first group of one or more normally-on devices Q1₁-Q1ₙ and wherein a second capacitor C6₂ and a second zener diode D3₂ are shown connected in parallel with one another between the source of the normally-off device and the common gate of the second group of one or more normally-on devices Q2₁-Q2ₙ and wherein a diode D2 and a resistor R1₁ are shown connected in series between the gate of the normally-off device Q4 and the electrical connection between the first capacitor C6₁ and the common gate of the first group of normally-on devices Q1₁-Q1ₙ and wherein the diode D2 and a resistor R1₂ are shown connected in series between the gate of the normally-off device Q4 and the electrical connection between the second capacitor C6₂ and the common gate of the second group of normally-on devices Q2₁-Q2ₙ.

FIGS. 10A and 10B are schematics showing voltages at various points in the device of FIG. 1B during operation wherein the device at turn-on is shown in FIG. 10A and the device after turn-off is shown in FIG. 10B.

FIGS. 11A-11C show switching waveforms for a switch as shown in FIG. 1B.

### DESCRIPTION OF THE VARIOUS EMBODIMENTS

For the purposes of interpreting this specification, the use of “or” herein means “and/or” unless stated otherwise or where the use of “and/or” is clearly inappropriate. The use of “a” herein means “one or more” unless stated otherwise or where the use of “one or more” is clearly inappropriate. The use of “comprise,” “comprises,” “comprising,” “include,” “includes,” and “including” are interchangeable and not intended to be limiting. Furthermore, where the description of one or more embodiments uses the term “comprising,” those skilled in the art would understand that, in some specific instances, the embodiment or embodiments can be alternatively described using the language “consisting essentially of” and/or “consisting of” It should also be understood that in some embodiments the order of steps or order for performing certain actions is immaterial so long as the present teachings remain operable. Moreover, in some embodiments two or more steps or actions can be conducted simultaneously.

Switches comprising a normally-off device and a normally-on high voltage device in cascode arrangement are described. The switches comprise a capacitor connected between the gate of the normally-on (e.g., high-voltage) device and the source of the normally-off (e.g., low-voltage) device. The capacitor can be used to recycle the gate charge and simplify control of the switching transition speed. In particular, the charge transferred in the Miller (i.e., gate-drain) capacitance during the turn-off transition can be used to provide the charge required for the next turn on period. This charge is stored in the capacitor connected between the gate of the normally-on device and the source of the normally-off device. By selection of the capacitance value of the capacitor, the switching speed can be defined and is quasi-independent of the switched current. This allows for better EMI (Electro-Magnetic Interference) control without having large passive elements (called snubbers) that dampen electrical oscillation. The addition of the capacitor is a significant improvement over conventional cascode circuits where the charge is not recycled and other techniques are used to control the switching speeds. Moreover, the use of a capacitor as described herein is virtually lossless and requires a minimum of components.

As used herein, “normally-on” means a device which conducts current in the absence of gate bias and requires a gate bias to block current flow. As used herein, “normally-off” means a device which blocks current in the absence of gate bias and conducts current when gate bias is applied. As used herein, “high voltage” is a voltage of 100 volts or greater and “low voltage” is a voltage less than 100 volts (e.g., 20-50 V).

As used herein, a component of a circuit which is “connected to” another component or point in the circuit or “connected between” two components or points in a circuit can be either directly connected or indirectly connected to the other component(s) or point(s) in the circuit. A component is directly connected to another component or point in the circuit if there are no intervening components in the connection whereas a component is indirectly connected to another component or point in the circuit if there are one or more intervening components in the connection. If a first component or point in a circuit is specified as being connected to a second component or point in the circuit via a third component, the third component is electrically connected between the first component or point in the circuit and the third component or point in the circuit. The first component or point in a circuit and third component can be directly or indirectly connected together. Similarly, the second component or point in a circuit and third component can be directly or indirectly connected together.

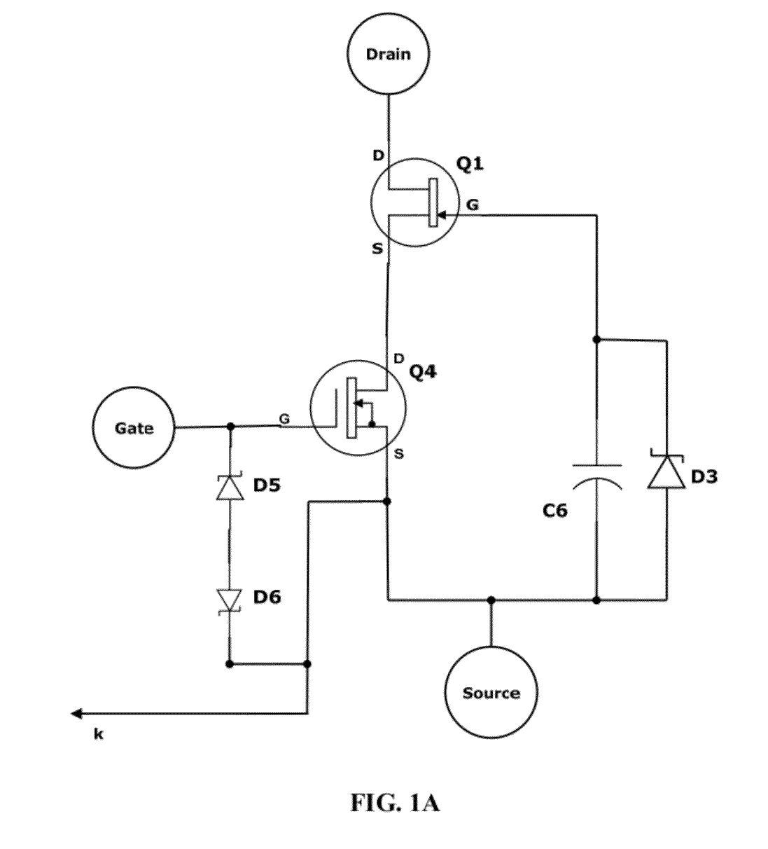

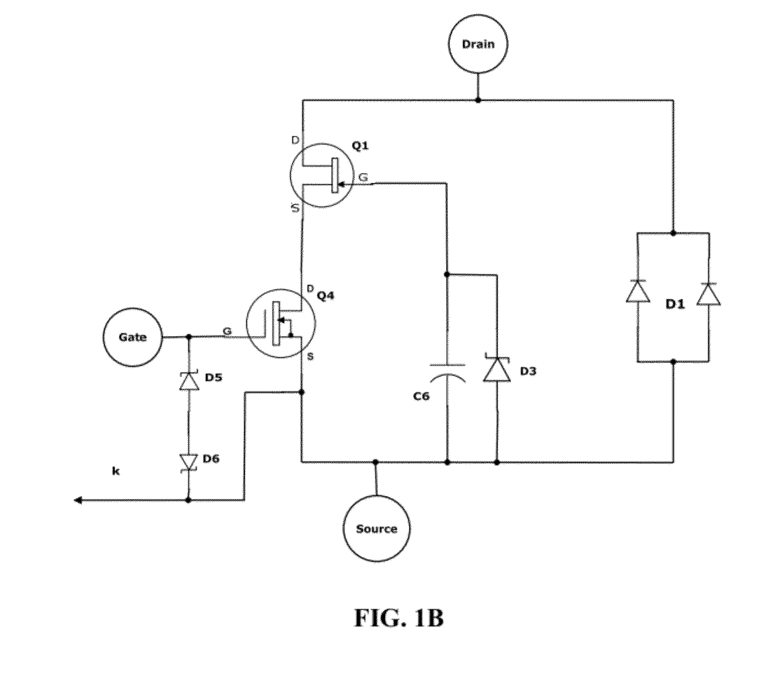

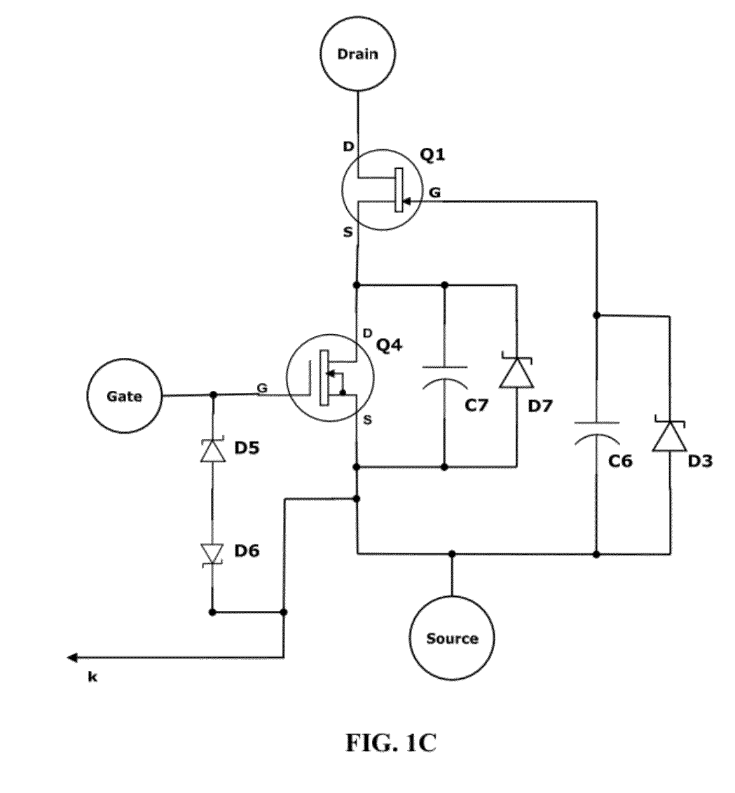

Several switches which include a capacitor connected between the source of a normally-off device and the gate of a normally-on device in a source-switched (i.e., cascode) configuration are described. A switch according to some embodiments is shown in FIG. 1A. FIG. 1A is a schematic of a switch comprising a normally-off device Q4 having a gate, a source and a drain and a normally-on device Q1 having a gate, a source and a drain in cascode arrangement wherein a capacitor C6 and a diode D3 are shown connected in parallel between the source of the normally-off device and the gate of the normally-on device. Although a zener diode D3 is shown in FIG. 1A, other types of diodes can also be used. As shown in FIG. 1A, the cathode of the zener diode D3 is connected to the gate of the normally-on device. Zener diode D3 can prevent the gate voltage of the normally on device from going negative while also preventing it from going too high which could force the normally-off device to go into avalanche. In FIG. 1A, “k” represents a Kelvin connection to the source of the normally-off device Q4. The Kelvin connection is optional and can be used in high power applications.

As also shown in FIG. 1A, a pair of zener diodes D5 and D6 are connected in series opposing arrangement between the gate and the source of the normally-off device. Zener diodes D5 and D6 shown in FIG. 1A are optional clamp diodes that can be used to prevent the gate of Q4 from exceeding operating limits. For example, zener diodes D5 and D6 can prevent damage to low-voltage switching device Q4 (e.g., a Si MOSFET or a SiC JFET) from spike voltages resulting from stray inductance and high di/dt. Diodes D5 and D6 as shown in FIG. 1A can be used in any of the embodiments described herein.

Normally-on device Q1 can be a high-voltage (e.g., 100V or greater), normally-on field effect transistor. Normally-off device Q4 can be a low-voltage (e.g., <100V), normally-off transistor.

FIG. 1B is a schematic of a switch which further comprises a pair of diodes D1 in parallel with one another connected between the source of the normally-off device and the drain of the normally-on device such that the cathodes of the diodes D1 are connected to the drain of the normally-on device. The diodes D1 are optional. The diodes D1 as shown in FIG. 1B can be used in any of the embodiments described herein. The diodes can reduce conduction losses when the switch is operating as a synchronous rectifier. In FIG. 1B, “k” represents a Kelvin connection to the source of the normally-off device Q4. The Kelvin connection is optional and can be used in high power applications. Although a zener diode D3 is shown in FIG. 1B, other types of diodes can also be used.

Depending upon the ratios of the output capacitances, a capacitor and/or zener diode can be added across the normally-off device(s) in the switch. FIG. 1C is a schematic of a switch which further comprises a capacitor C7 and a zener diode D7 across the normally-off device Q4. Zener diode D7 can relieve the normally-off device Q4 of avalanche energy if the drain voltage goes too high. Capacitor C7 can slow down turn-off. The capacitor and/or zener diode as shown in FIG. 1C can be used in any of the embodiments described herein. In FIG. 1C, “k” represents a Kelvin connection to the source of the normally-off device Q4. The Kelvin connection is optional and can be used in high power applications. Although a zener diode D3 is shown in FIG. 1C, other types of diodes can also be used.

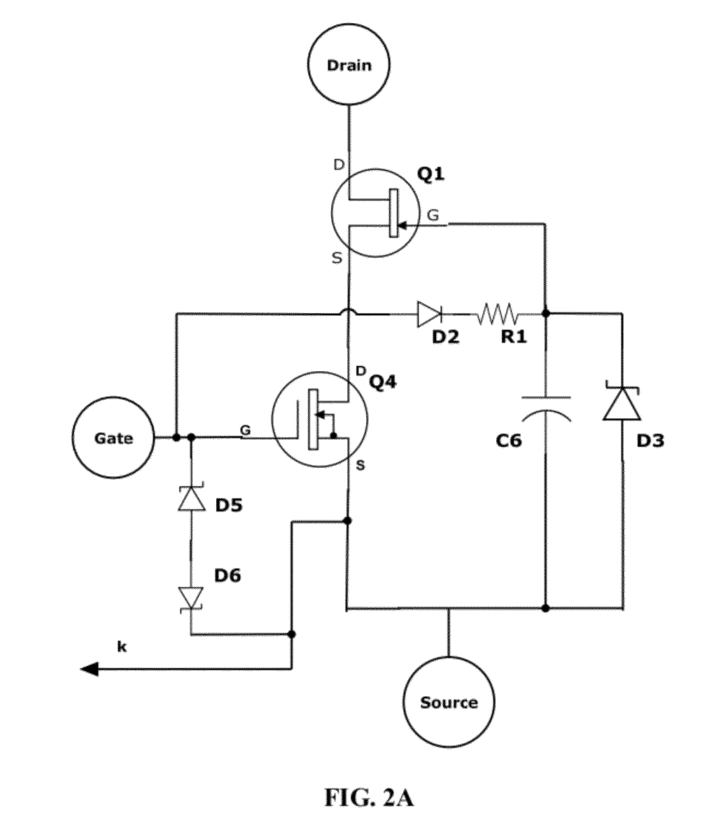

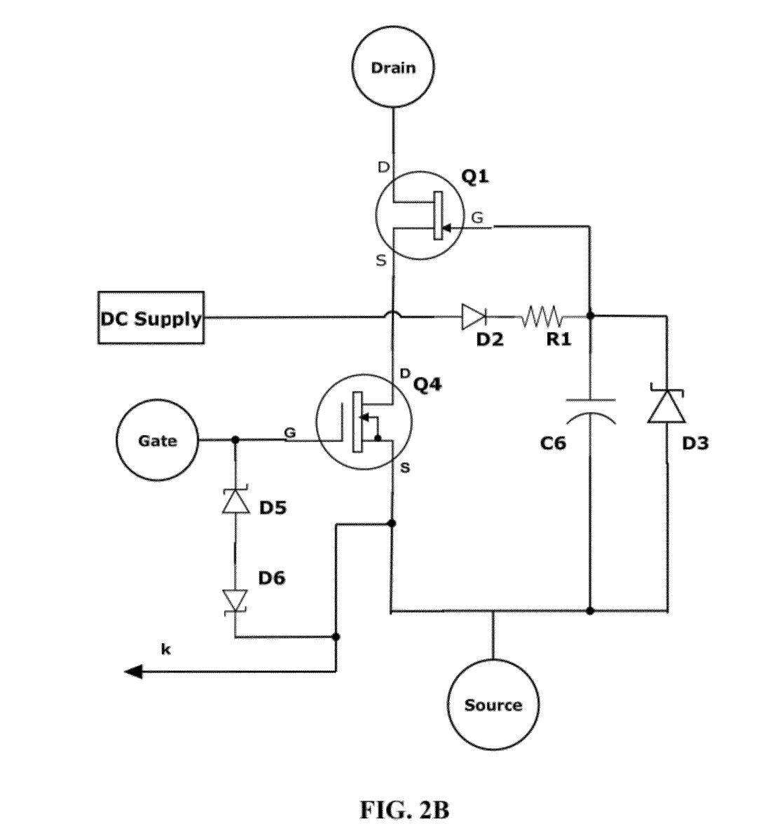

The switches described herein can be combined in a single package with various enhancements to further modify the switching speed and reduce the conduction losses. According to some embodiments, the conduction losses can be reduced by adding a small DC bias to the capacitor C6, either from the gate drive or from a DC supply. An embodiment wherein a DC bias is added to the capacitor C6 from the gate drive is shown in FIG. 2A. As shown in FIG. 2A, a diode D2 and a resistor R1 are connected in series between the gate of the normally-off device and the electrical connection between the capacitor C6 and the gate of the normally-on device. The diode D2 and the resistor R1 shown in FIG. 2A can be used in any of the embodiments described herein. In FIG. 2A, “k” represents a Kelvin connection to the source of the normally-off device Q4. The Kelvin connection is optional and can be used in high power applications. Although a zener diode D3 is shown in FIG. 2A, other types of diodes can also be used.

An embodiment wherein a DC bias is added to the capacitor C6 from a DC power supply is shown in FIG. 2B. As shown in FIG. 2B, the DC power supply is connected to the electrical connection between the capacitor C6 and the gate of the normally-on device Q1 via a diode D2 and a resistor R1 in series. The DC power supply, diode D2 and resistor R1 shown in FIG. 2B can be used in any of the embodiments described herein. In FIG. 2B, “k” represents a Kelvin connection to the source of the normally-off device Q4. The Kelvin connection is optional and can be used in high power applications. Although a zener diode D3 is shown in FIG. 2B, other types of diodes can also be used.

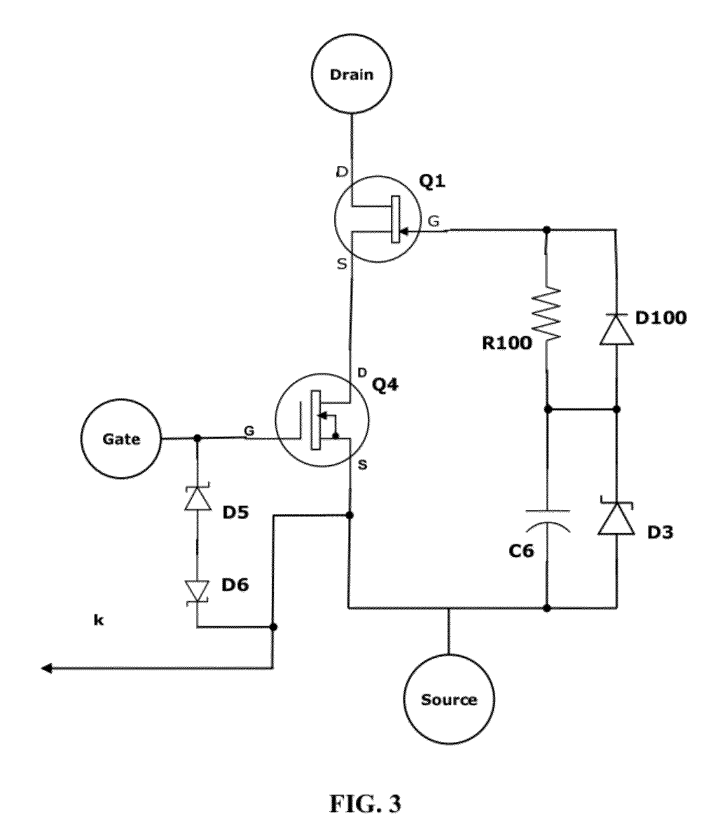

FIG. 3 is a schematic of a switch comprising a normally-off device Q4 having a gate, a source and a drain and a normally-on device Q1 having a gate, a source and a drain connected in cascode arrangement. As shown in FIG. 3, a capacitor C6 and a diode D3 are shown connected in parallel with one another between the source of the normally-off device Q4 and the gate of the normally-on device Q1. Although a zener diode D3 is shown in FIG. 3, other types of diodes can also be used. As also shown in FIG. 3, a resistor R100 and a diode D100 are shown connected in parallel with one another and in series with the capacitor C6 and zener diode D3 between the capacitor C6 and zener diode D3 and the gate of the normally-on device. As also shown in FIG. 3, the cathodes of the zener diode D3 and the diode D100 are both connected to the gate of the normally-on device. This arrangement can be used to speed up the turn-on of the switch. Optional clamp diodes D5 and D6 are also shown in FIG. 3. The resistor R100 and the diode D100 as shown in FIG. 3 can be used in any of the embodiments described herein. In FIG. 3, “k” represents a Kelvin connection to the source of the normally-off device Q4. The Kelvin connection is optional and can be used in high power applications.

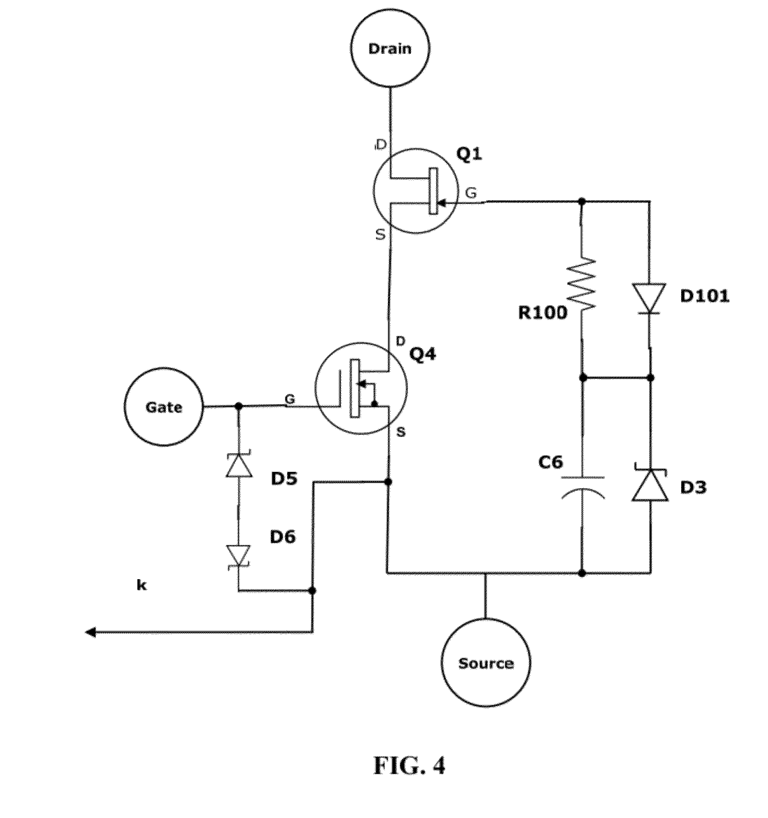

FIG. 4 is a schematic of a switch comprising a normally-off device Q4 having a gate, a source and a drain and a normally-on device Q1 having a gate, a source and a drain connected in cascode arrangement wherein a capacitor C6 and a diode D3 are shown connected in parallel with one another between the source of the normally-off device Q4 and the gate of the normally-on device Q1. Although a zener diode D3 is shown in FIG. 4, other types of diodes can also be used. As shown in FIG. 4, a resistor R100 and a diode D101 are also shown connected in parallel with one another and in series with the capacitor C6 and the zener diode D3 between the capacitor C6 and zener diode D3 and the gate of the normally-on device. As also shown in FIG. 4, the cathode of the zener diode D3 and the anode of the diode D101 are connected to the gate of the normally-on device. This arrangement can be used to speed up the turn-off of the switch. Optional clamp diodes D5 and D6 are also shown in FIG. 4. The resistor R100 and the diode D101 as shown in FIG. 4 can be used in any of the embodiments described herein. In FIG. 4, “k” represents a Kelvin connection to the source of the normally-off device Q4. The Kelvin connection is optional and can be used in high power applications.

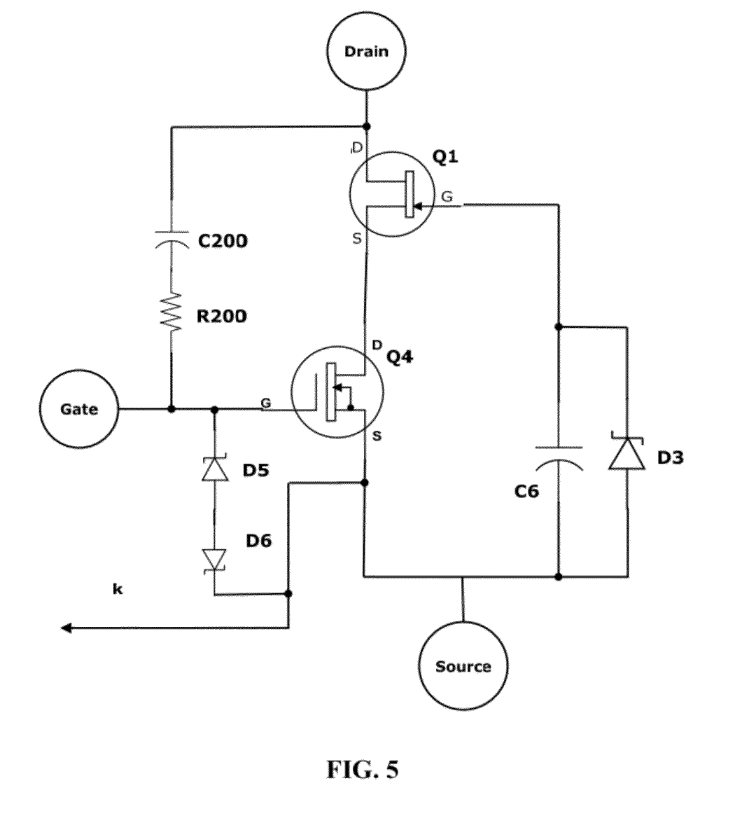

FIG. 5 is a schematic of a switch as set forth in FIG. 1A which also comprises a resistor 8200 and a capacitor C200 connected in series between the gate of the normally-off device and the drain of the normally-on device. The capacitor C200 can be used to control the switching speed of the switch. Optional clamp diodes D5 and D6 are also shown in FIG. 5. The resistor 8200 and the capacitor C200 connected in series between the gate of the normally-off device and the drain of the normally-on device as shown in FIG. 5 can be used in any of the embodiments described herein. In FIG. 5, “k” represents a Kelvin connection to the source of the normally-off device Q4. The Kelvin connection is optional and can be used in high power applications. Although a zener diode D3 is shown in FIG. 5, other types of diodes can also be used.

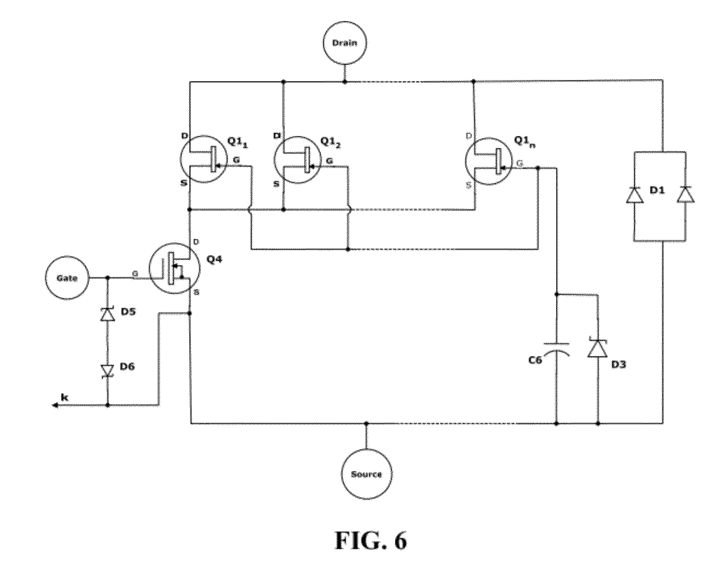

Switches comprising a plurality of normally-on devices and either a single or a plurality of normally-off devices are also provided. Schematics of embodiments comprising a plurality of normally-on devices and either a single or a plurality of normally-off devices are shown in FIGS. 6-9 and are described below. Although a zener diode D3 is shown in these figures, other types of diodes can also be used.

FIG. 6 is a schematic of a switch comprising a single normally-off device Q4 having a gate, a source and a drain and a plurality of normally-on devices Q1₁-Q1ₙ each having a gate, a source and a drain wherein the gates of the normally-on devices Q1₁-Q1ₙ are connected together to form a common gate and wherein a single capacitor C6 and a single zener diode D3 are shown connected in parallel with one another between the source of the normally-off device Q4 and the common gate of the normally-on devices Q1₁-Q1ₙ. In FIG. 6, diodes D1 are also shown connected parallel with one another between the source of the normally-off device Q4 and the common drain of the normally-on devices Q1₁-Q1ₙ. The diodes D1 are optional. Optional clamp diodes D5 and D6 are also shown in FIG. 6. In FIG. 6, “k” represents a Kelvin connection to the source of the normally-off device Q4. The Kelvin connection is optional and can be used in high power applications.

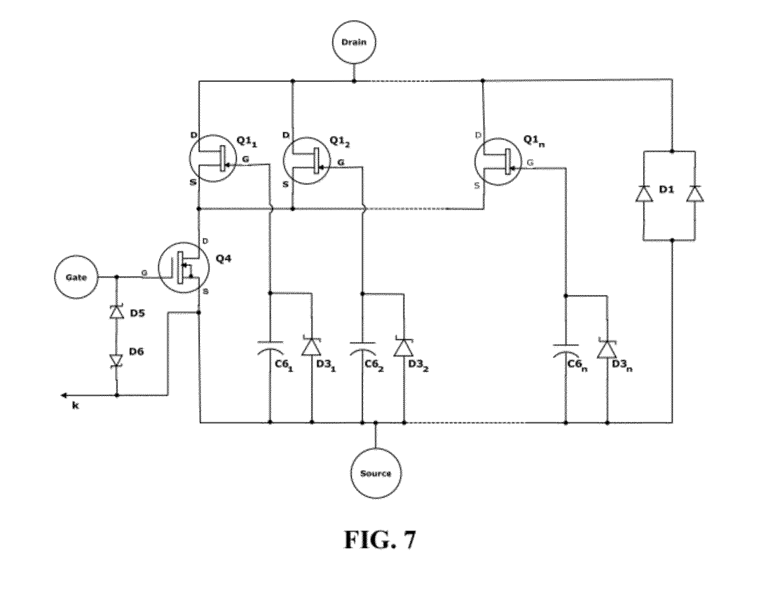

FIG. 7 is a schematic of a switch comprising a single normally-off device Q4 having a gate, a source and a drain and a plurality of normally-on devices Q1₁-Q1ₙ each having a gate, a source and a drain wherein separate capacitors C6ₙ and zener diodes D3ₙ are shown connected in parallel with one another between the source of the normally-off device Q4 and the gates of each of the normally-on devices Q1₁-Q1ₙ. In FIG. 7, diodes D1 are also shown connected parallel with one another between the source of the normally-off device Q4 and the common drain of the normally-on devices Q1₁-Q1ₙ. The diodes D1 are optional. Optional clamp diodes D5 and D6 are also shown in FIG. 7. In FIG. 7, “k” represents a Kelvin connection to the source of the normally-off device Q4. The Kelvin connection is optional and can be used in high power applications.

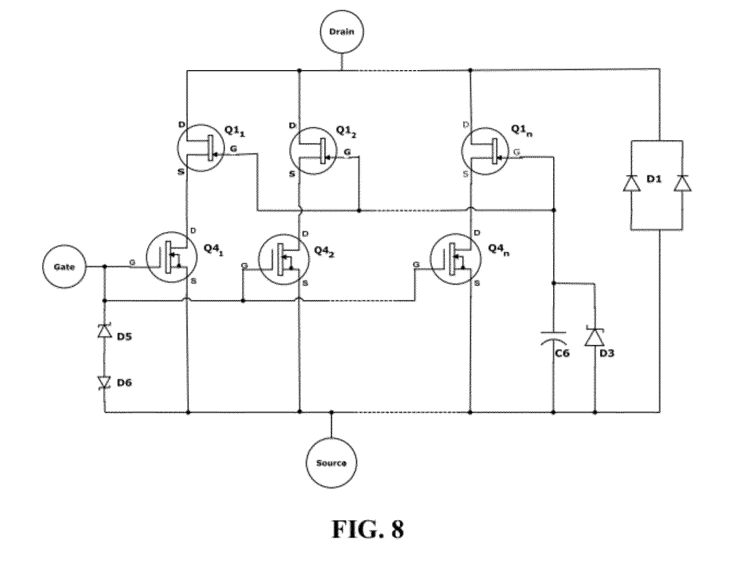

FIG. 8 is a schematic of a switch comprising a plurality of normally-off devices Q4₁-Q4ₙ each having a gate, a source and a drain and a plurality of normally-on devices Q1₁-Q1ₙ each having a gate, a source and a drain. As shown in FIG. 8, the gates of the normally-on devices Q1₁-Q1ₙ are connected together to form a common gate. As shown in FIG. 8, the gates of the normally-off devices Q4₁-Q4ₙ are connected together to form a common gate, the source of the normally-off devices Q4₁-Q4ₙ are connected together to form a common source and the drains of each of the normally-off devices Q4₁-Q4ₙ are connected to the source of one of the plurality of normally-on devices. As also shown in FIG. 8, a single capacitor C6 and a single zener diode D3 are connected in parallel with one another between the common source of the normally-off devices and the common gate of the normally-on devices. In FIG. 8, diodes D1 are also shown connected in parallel with one another between the common source of the normally-off devices Q4₁-Q4ₙ and the common drain of the normally-on devices Q1₁-Q1ₙ. The diodes D1 are optional. Optional clamp diodes D5 and D6 are also shown in FIG. 8.

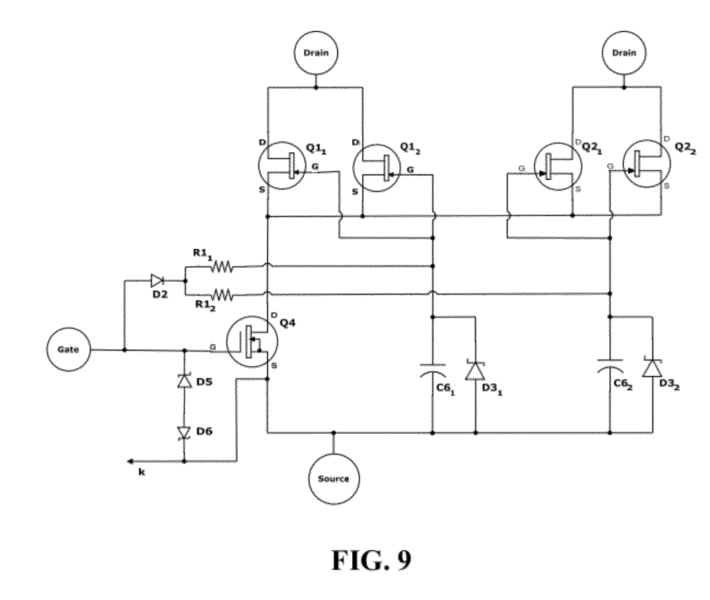

FIG. 9 is a schematic of a switch comprising a single normally-off device Q4 each having a gate, a source and a drain and two groups of normally-on devices Q1₁-Q1ₙ and Q2₁-Q2ₙ each having a gate, a source and a drain. As shown in FIG. 9, the gates of a first group of the normally-on devices Q1₁ and Q1₂ are connected together to form a common gate for the first group of normally on devices and the gates of a second group of the normally-on devices Q2₁ and Q2₂ are connected together to form a common gate for the second group of normally-on devices. As also shown in FIG. 9, a first capacitor C6₁ and a first zener diode D3₁ are shown connected in parallel with one another between the source of the normally-off device and the common gate of the first group of normally-on devices and a second capacitor C6₂ and a second zener diode D3₂ are shown connected in parallel with one another between the source of the normally-off device and the common gate of the second group of normally-on devices. As also shown in FIG. 9, a diode D2 and a resistor R1₁ are shown connected in series between the gate of the normally-off device and the common gate of the first group of normally-on devices and the diode D2 and a resistor R1₂ are shown connected in series between the gate of the normally-off device and the common gate of the second group of normally-on devices. Diode D2 and resistors R1₁ and R1₂ are optional. Optional clamp diodes D5 and D6 are also shown in FIG. 9. In FIG. 9, “k” represents a Kelvin connection to the source of the normally-off device Q4. The Kelvin connection is optional and can be used in high power applications.

Because the circuit only has three terminals, it can be mounted and packaged as a three terminal device and used in place of a single transistor.

According to some embodiments, the normally-on device Q1 can be a high-voltage device such as a high voltage JFET (e.g., a SiC JFET). The normally-on device does the main power switching. The high-voltage device can have a voltage rating of greater than 100 V. According to some embodiments, the normally-on device can be a SiC JFET as disclosed in U.S. Pat. No. 6,767,783, which is incorporated by reference herein in its entirety. A suitable commercially available normally-on device is a 1200 V normally-on SiC JFET manufactured by SemiSouth Laboratories, Inc. under the designation SJDP120R085.

According to some embodiments, Q4 can be a low voltage switching device an exemplary non-limiting example of which is a Si MOSFET. The low-voltage device can have a voltage rating of less than 100 V. An exemplary low-voltage device has a voltage rating of about 40 V (e.g., 38-42 V) and an Rd, of 5-10% of the resistance of the normally-on device Q1. The switching of this device allows the main switch to conduct.

The capacitor C6 connected between the gate of the normally-on device and the source of the normally-off device is used to re-circulate the charge in the gate drain capacitance of the main switch. The capacitance value of the capacitor can be selected to provide a switch having a desired switching speed. According to some embodiments, the capacitor C6 can have a capacitance value of 1000-100000 nF. According to some embodiments, the capacitor C6 can have a capacitance value of 2200-6800 pF

The zener diode D3 connected between the gate of the normally-on device and the source of the normally-off device in parallel with the capacitor C6 typically has a blocking voltage of about 20 V (e.g., 18-22 V). The zener diode D3 can prevent the gate of the normally-on device Q1 from going negative, so it cannot be turned on. The zener diode D3 can also prevent the gate of the normally-on device Q1 from going too high, due to avalanche or leakage current so that Q4 does not go into avalanche.

The series opposing zener diodes D5 and D6 between the gate and source of the normally-off device Q4 are clamp diodes which can prevent the gate of Q4 from exceeding the manufacturers limits due to, for example, high spike voltages resulting from stray inductance and high di/dt. Diodes D5 and D6 are optional.

Diodes D1 are optional reverse conduction diodes. In some application with low switching frequencies the conduction losses may be lower using the extra diodes than the synchronous rectifier capabilities of Q4/Q1.

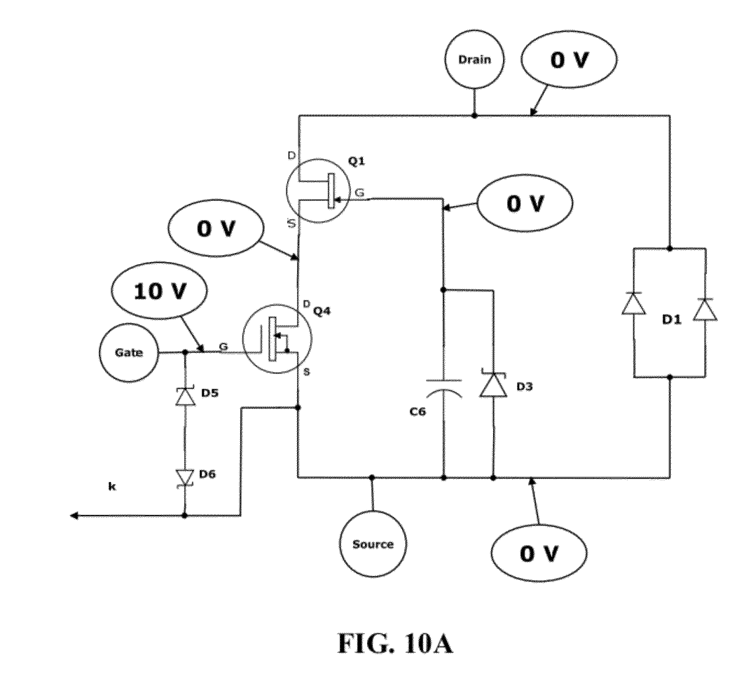

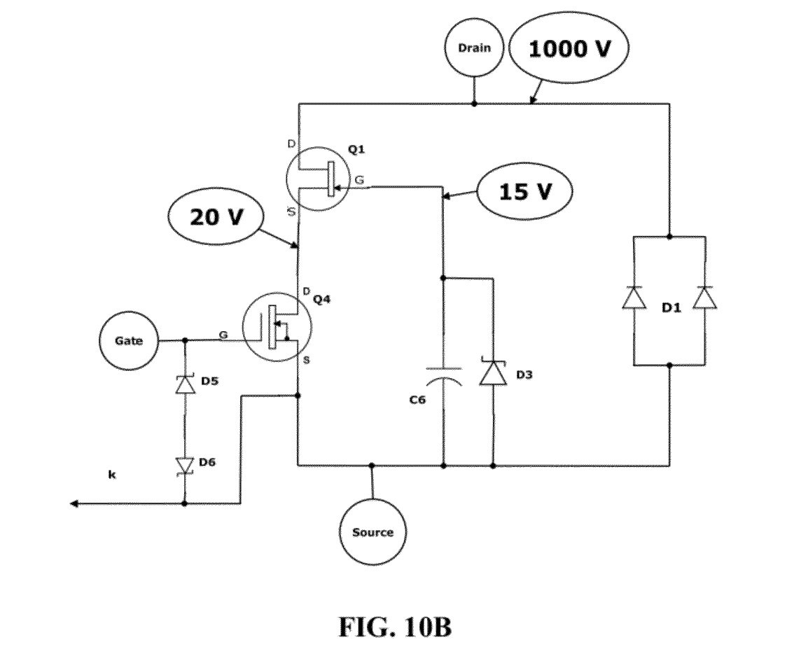

FIGS. 10A and 10B are schematics showing voltages at various points in the device during operation. As shown in FIGS. 10A and 10B, the source of Q4 is raised until the threshold of the normally-on device is reached and no more current flows. As a result, no switching occurs. The device at turn-on is shown in FIG. 10A. As shown in FIG. 10A, the gate of Q4 is high (10 V) and the drain of Q4 is low (0 V), and as a result the normally-on device Q1 is conducting. During turn-on transition, C6 is discharged by drain-gate capacitance of Q4 so it goes negative but is clamped by zener diode D3.

The device after turn-off is shown in FIG. 10B. As shown in FIG. 10B, the gate of normally-off device Q4 goes to zero, the normally-on device Q1 conducts and lifts the drain of the normally-off device Q4, the drain-gate capacitance of Q1 lifts capacitor C6, and the maximum voltage is clamped by D3.

In the switches described herein, the gate charge for the normally-off device Q4 during the turn-on transition comes from the capacitor C6 which speeds up turn-on. The capacitor C6 is charged during turn-off. In particular, after turn-off the drain-gate capacitance of the normally-on device Q1 lifts the voltage of the capacitor C6.

The capacitance value of the capacitor C6 can be varied to influence the switching behavior. For example, a smaller capacitance for C6 will provide a faster turn-on but a slower turn-off. The capacitance C_{ds} of the normally-on device can be used to charge Q4 output capacitance.

Circuits comprising switches as set forth above are also provided. The switches can be used in any application which employs a switching transistor. Exemplary circuits include power supplies such as buck, boost, forward, half-bridge and Cuk.

### EXPERIMENTAL

The practice of this invention can be further understood by reference to the following examples, which are provided by way of illustration only are not intended to be limiting.

A switch as described herein was manufactured and tested. The switch comprised a single normally-on device and a single normally-off device and had a configuration as shown in FIG. 1B. The normally-on device Q1 was a SiC JFET. The normally-off device was a Si MOSFET. The capacitor C6 used in the switch had a capacitance of 4700 pF. The zener diodes D3, D5 and D6 used in the switch each had a zener voltage of 18 V. The switch also included a pair of diodes D1 as shown in FIG. 1B.

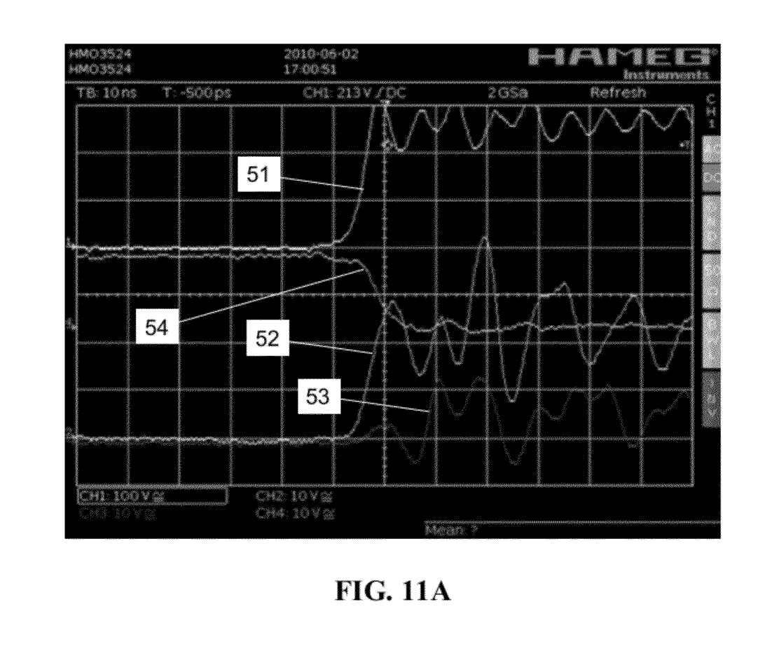

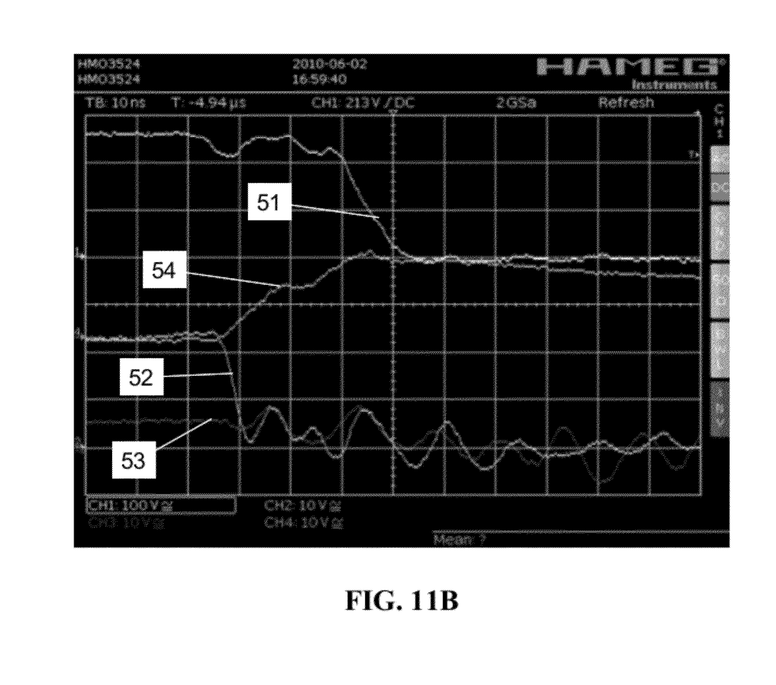

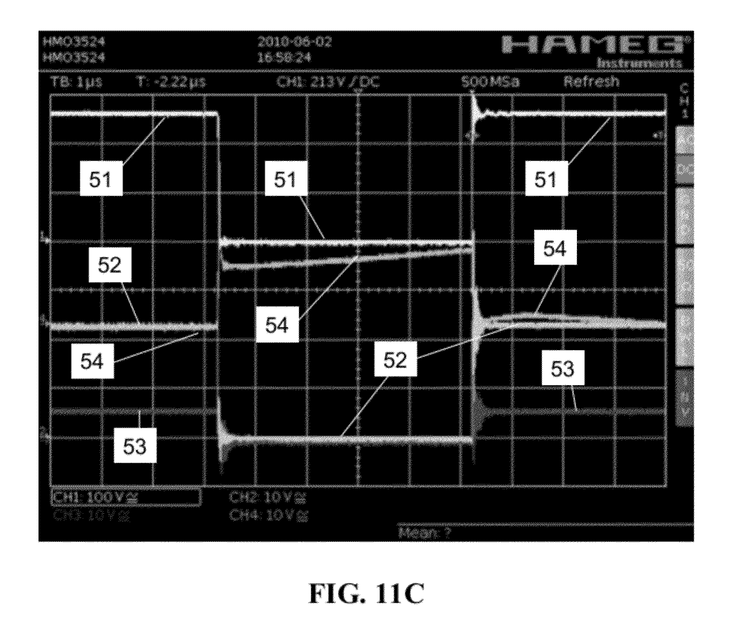

FIGS. 11A-11C show switching waveforms for the switch. FIG. 11A is the switching waveform for the switch at turn-off. FIG. 11B is the switching waveform for the switch at turn-on. In FIGS. 11A-11C, 51 is the voltage as measured at the drain of the normally-on device (i.e., the cascode drain), 52 is the voltage as measured at the source of the normally-on device, 53 is the voltage as measured at the gate of the normally-on device and 54 is the voltage as measured at the drain of the normally-off device (i.e., the cascode source). The measured di/dt was ˜2 A/nS but the probe used was a 100 MHz probe so the actual value of di/dt could be faster.

As shown in FIGS. 11A-11C, the gate of the normally-off device goes high (e.g., 10 V) resulting in the turn-on of the normally-on device Q1. During turn-on, the voltage of C6 falls to zero and supplies current into the gate of the normally-off device Q4 compensating for the drain gate capacitance of Q4. This speeds up turn-on of the switch.

While the foregoing specification teaches the principles of the present invention, with examples provided for the purpose of illustration, it will be appreciated by one skilled in the art from reading this disclosure that various changes in form and detail can be made without departing from the true scope of the invention.

What is claimed is:

1. A switch comprising:
a first normally-on semiconductor device comprising a gate, a source and a drain;
a first normally-off semiconductor device comprising a gate, a source and a drain;
a first capacitor; and
a first diode;
wherein the source of the first normally-on semiconductor device is connected to the drain of the first normally-off semiconductor device;
wherein the gate of the first normally on semiconductor device is connected to the source of the first normally-off semiconductor device via a first capacitor; and
wherein the first diode is connected between the gate of the first normally on semiconductor device and the source of the first normally-off semiconductor device in parallel with the first capacitor, wherein the cathode of the first diode is connected to the gate of the first normally-on semiconductor device and the anode of the first diode is connected to the source of the first normally-off semiconductor device.

2. The switch of claim 1, wherein the first diode is a first zener diode.

3. The switch of claim 2, wherein the first zener diode has a zener voltage of 15-25 V.

4. The switch of claim 1, further comprising a second zener diode and a third zener diode connected in series opposing arrangement between the gate and source of the first normally-off semiconductor device.

5. The switch of claim 1, further comprising first and second diodes connected in parallel with one another between the drain of the first normally-on semiconductor device and the source of the first normally-off semiconductor device such that the cathodes of each of the first and second diodes are connected to the drain of the first normally-on semiconductor device.

6. The switch of claim 1, further comprising a diode and a resistor connected in series between the gate of the first normally-off semiconductor device and the electrical connection between the first capacitor and the gate of the first normally-on semiconductor device, wherein the anode of the diode is connected to the gate of the first normally-off semiconductor device.

7. The switch of claim 1, further comprising a resistor and a diode arranged parallel to one another and in series with the first capacitor between the gate of the first normally-on semiconductor device and the first capacitor.

8. The switch of claim 7, wherein the cathode of the diode is connected to the gate of the first normally on semiconductor device.

9. The switch of claim 7, wherein the anode of the diode is connected to the gate of the first normally on semiconductor device.

10. The switch of claim 1, further comprising a resistor and a second capacitor arranged in series between the gate of the first normally-off semiconductor device and the drain of the first normally-on semiconductor device.

11. The switch of claim 1, wherein the first normally-on semiconductor device is a high-voltage device.

12. The switch of claim 1, wherein the first normally-on semiconductor device is a junction field-effect transistor.

13. The switch of claim 1, wherein the first normally-on semiconductor device is a SiC junction field-effect transistor.

14. The switch of claim 1, wherein the first normally-off semiconductor device is a low-voltage device.

15. The switch of claim 1, wherein the first normally-off semiconductor device is a metal-oxide semiconductor field-effect transistor.

16. The switch of claim 1, wherein the first normally-off semiconductor device is a Si metal-oxide semiconductor field-effect transistor.

17. The switch of claim 1, wherein:
the switch further comprises one or more additional normally-on semiconductor devices;
the drain of each of the one or more additional normally-on semiconductor devices is connected to the drain of the first normally-on semiconductor device;
the source of each of the one or more additional normally-on semiconductor devices is connected to the drain of the first normally-off semiconductor device; and
the gate of the first normally-on semiconductor device is connected to the gates of each of the one or more additional normally-on semiconductor devices to form a common gate and wherein the common gate is connected to the source of the second normally-off semiconductor device via the first capacitor.

18. The switch of claim 1, wherein:
the circuit further comprises one or more additional normally-on semiconductor devices;
the drain of each of the one or more additional normally-on semiconductor devices is connected to the drain of the first normally-on semiconductor device;
the source of each of the one or more additional normally-on semiconductor devices is connected to the drain of the first normally-off semiconductor device; and
each of the gates of the one or more additional normally-on semiconductor devices is connected to the source of the second normally-off semiconductor device via a capacitor.

19. The switch of claim 1, wherein:
the circuit further comprises one or more additional normally-on semiconductor devices and one or more additional normally-off semiconductor devices;
the drain of each of the one or more additional normally-on semiconductor devices is connected to the drain of the first normally-on semiconductor device;
the gate of each of the one or more additional normally-on semiconductor devices is connected to the gate of the first normally-on semiconductor device to form a common gate and wherein the common gate is connected to the source of the first normally-off semiconductor device via the first capacitor;
the source of each of the one or more additional normally-on semiconductor devices is connected to the drain of a separate one of the one or more additional normally-off semiconductor devices;
the source of each of the one or more additional normally-off semiconductor devices is connected to the source of the first normally-off semiconductor device; and
the gate of each of the one or more additional normally-off semiconductor devices is connected to the gate of the first normally-off semiconductor device.

20. The switch of claim 1, wherein the first capacitor has a capacitance of 1000-100000 nF.

21. The switch of claim 1, wherein the first capacitor has a capacitance of 2200-6800 pF.

22. The switch of claim 1, wherein the first capacitor has a voltage rating of at least 25V.

23. The switch of claim 1, wherein the first normally-on semiconductor device is a wide band-gap junction field-effect transistor.

24. The switch of claim 1, further comprising a DC voltage supply, wherein the DC voltage supply is adapted to supply a DC bias to the first capacitor.

25. The switch of claim 24, further comprising a diode and a resistor connected in series between the DC voltage supply and the connection between the first capacitor and the gate of the first normally-on semiconductor device, wherein the anode of the diode is connected to the gate of the first normally-off semiconductor device.

26. The switch of claim 6, further comprising a DC voltage supply connected to the gate of the normally-off semiconductor device, wherein the DC voltage supply is adapted to supply a DC bias to:
the first capacitor via the diode and the resistor connected in series between the gate of the first normally-off semiconductor device and the connection between the first capacitor and the gate of the first normally-on semiconductor device; and
the gate of the normally-off semiconductor device.

27. A circuit comprising a switch as set forth in claim 1.
